(19) United States
(12) Patent Application Publication
(10) Pub. No.: US 2006/0256522 A1
(43) Pub. Date: Nov. 16, 2006

(54) Method and apparatus to maintain chassis air flow during replacement of a fan module in a fan tray

(75) Inventors: Wen Wei, Beaverton, OR (US); Ron W. Smith, Portland, OR (US); Jagadeesh Radhakrishnan, Folsom, CA (US)

Correspondence Address: Daly, Crowley, Mofford & Durkee, LLP;c/o PortfolioIP, P.O. Box 52050, Minneapolis, MN, 55402, US

(73) Assignee: Intel Corporation

(21) Appl. No.: 11/125,855

(22) Filed: May 10, 2005

(51) Int. Cl. H05K 7/20

(52) U.S. Cl. 361/695

(57) ABSTRACT

Method and apparatus for providing a chassis having an extendible fan tray with a extending from the fan tray to the chassis to maintain air flow while the fan tray is extended from the chassis. Fan modules in the fan tray can be replaced while maintaining air flow.

### CROSS REFERENCE TO RELATED APPLICATIONS

Not Applicable.

### STATEMENT REGARDING FEDERALLY SPONSORED RESEARCH

Not Applicable.

### BACKGROUND

As is known in the art, increasing circuit densities and clock speeds increase power consumption and heat generation. For example, network servers have relatively dense circuit cards known as blades, such as single board computers (SBCs), inside the chassis that can generate significant amounts of heat.

In a typical chassis, fans are used to force air flow into the chassis from an input air plenum through SBC arrays. The air in the chassis is then exhausted from a rear of the chassis, such as via an output air plenum, to provide adequate cooling to the silicon components on the circuit boards. Telecommunication equipment, for example, requires high reliability and redundancy to ensure that the system continues operation when fan module failures occur. When a fan is faulted, the failed fan module has to be replaced. Usually fans are grouped and assembled in single or multiple fan trays.

To replace a faulty fan in a conventional chassis, the entire fan tray including the operational fans in the same fan tray has to be removed from the chassis in order to swap out the faulty fan with a replacement. During the time the fan tray is removed from the chassis, the equipment continues to operate at full capacity. That is, the faulty fan module is hot-swapped with a new fan module.

Conventional chassis configurations include single and dual fan tray arrangements. For a single fan tray chassis configuration, the equipment has essentially no cooling airflow while the fan tray is out of the chassis during the hot swap process. A service technician must complete the replacement in less than a given time, e.g., one minute, to meet specification requirements. Such a fan replacement process can degrade silicon performance for the circuit board components and increase the mean time between failures (MTBF) due to the periods of reduced airflow. Such a process may also be relatively costly since when one fan unit fails, all the fans in a fan tray unit may be replaced. And while dual fan tray configurations may provide a reduced air flow during the time one of the fan trays is removed from the chassis, circuit boards remote from the operational fan tray may have insufficient air flow.

### BRIEF DESCRIPTION OF THE DRAWINGS

The exemplary embodiments contained herein will be more fully understood from the following detailed description taken in conjunction with the accompanying drawings, in which:

FIG. 1 is a pictorial representation of a chassis having a fan tray in a first position;

FIG. 2 is a pictorial representation of a chassis having a fan tray in a second position and a duct to maintain air flow in the chassis;

FIG. 3 is a schematic depiction of air flow through a chassis;

FIG. 4 is a pictorial representation of a fan tray having a removable fan module;

FIG. 5 is a front view of a chassis having a fan tray;

FIG. 6 is a pictorial representation of a fan tray and assembly with fan connectors;

FIG. 7 is a pictorial representation of a chassis having a fan tray in a second position extended from the chassis; and

### DETAILED DESCRIPTION

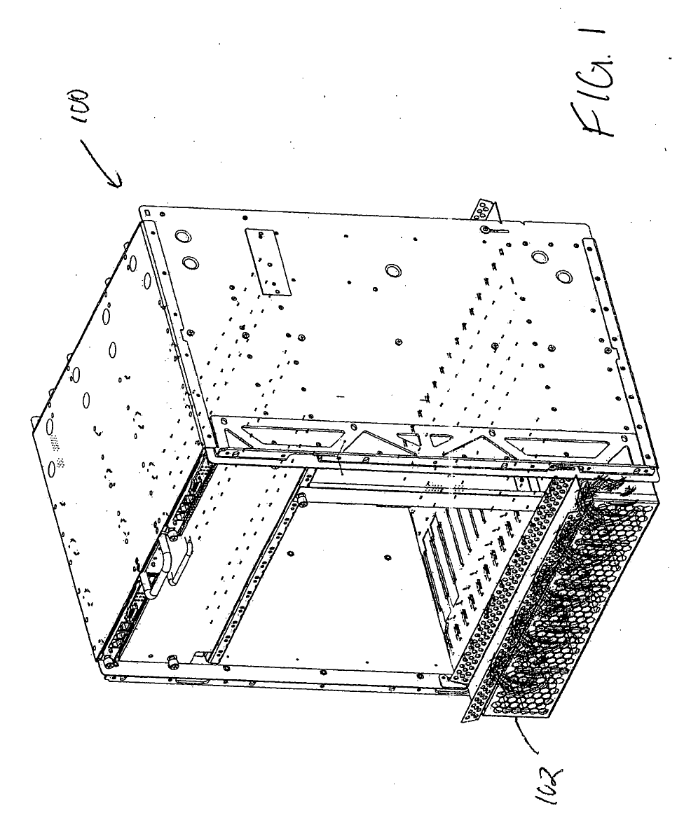

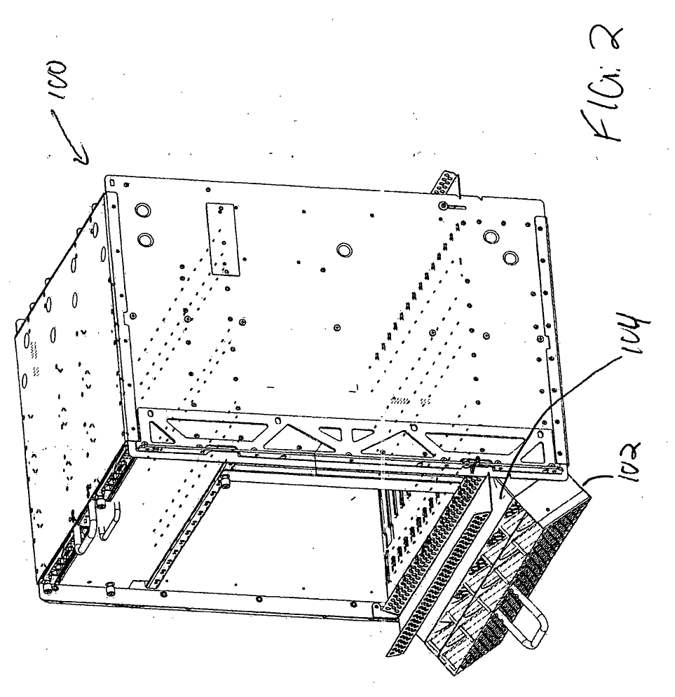

FIGS. 1 and 2 shows an exemplary chassis 100 having a fan tray 102 that can be moved between a first position (FIG. 1) and a second position (FIG. 2) while maintaining a level of air flow through the chassis. In general, when the fan tray 102 is moved, such as by rotation, to the second position for swapping out a fan module for example, air flow forced by the fans is maintained by a duct 104 coupled to the fan tray 102.

With this arrangement, while a fan module is swapped out of the fan tray 102, circuit cards, e.g., blades, contained within the chassis 100 are still cooled via forced air flow since the duct 104 maintains a flow path to the input air plenum in the chassis, as described more fully below.

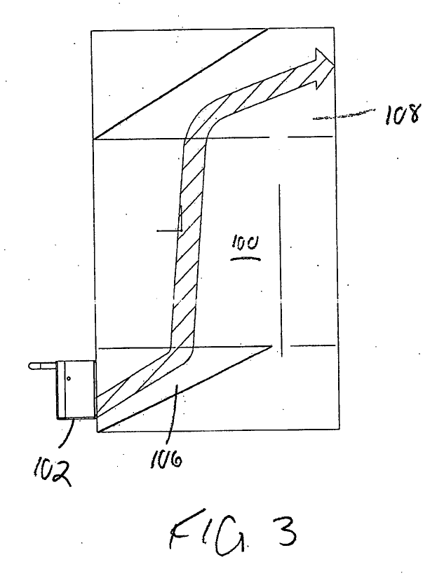

FIG. 3 shows an exemplary flow of air from the fan tray 102 through an input air plenum 106 into the chassis and out via an output air plenum 108. As is well known to one of ordinary skill in the art, air is forced into a chassis containing circuit cards to cool the integrated circuits and components on the circuit cards. Without adequate cooling, integrated circuits and components will rapidly fail due to continuous heat dissipation and excess operating temperatures.

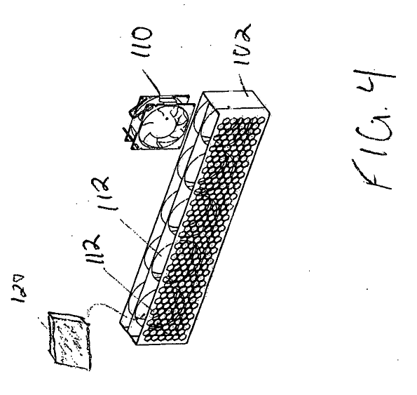

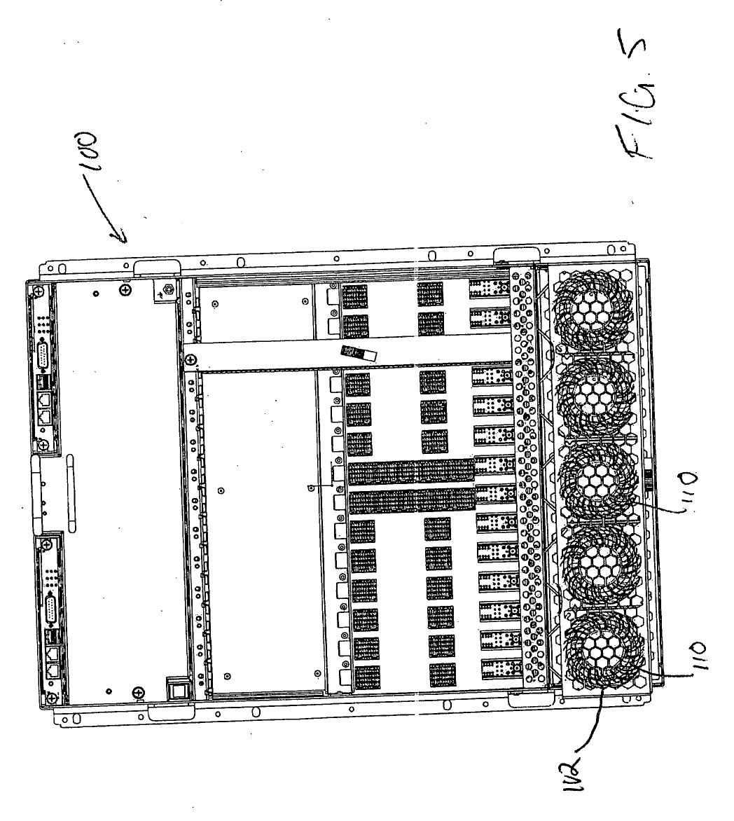

In an exemplary embodiment, as shown in FIGS. 4 and 5, the fan tray 102 includes a series of fan modules 110 removably coupled to the fan tray. Each fan module 110 forces intake air through respective channels 112 in the fan tray and into the chassis 100.

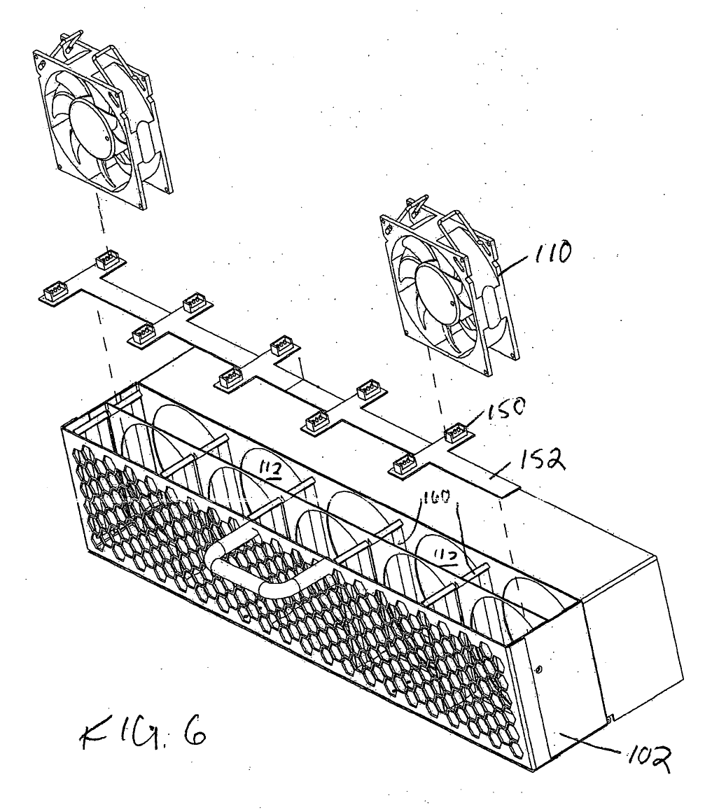

As shown in FIG. 6, in one embodiment each fan module 110 has a connector that can be coupled to a corresponding connector 150 secured to a rigid assembly 152 that can be positioned in the bottom of the fan tray 102. The assembly 152 can be connected to back plane of the chassis for energizing the fans through flat-ribbon cables or flex-connectors, for example. It will be appreciated that this arrangement facilitates hot-swapping faulty fan modules 110.

The fan tray 102 can include guides 160 that form a slot into which the fan module 110 can be inserted. The guides, which can extend from the assembly 152, ensure that as a user inserts the replacement fan module 110 into the slot the connectors mate properly.

As shown in the illustrated embodiments, the fan tray 102 can be rotated to the second position to enable a user to plug in replacement fan modules and remove faulty fan modules 104 without removing the fan tray 102 from the chassis 100. The duct 104 extends from the chassis to the fan tray 102 to prevent airflow bypass. That is, if the duct 104 were not present, the amount of air flowing into the chassis would be dramatically reduced since air would exit open regions between the fan tray 102 and the input air plenum. The duct 104 enables the operational and functional fan modules 110 in the fan tray to continue to force air into the chassis.

With this arrangement, the rotatable fan tray 102 and duct 104 combine to maximize airflow through the chassis for circuit board cooling during a hot swap of a faulty fan module 110. By maintaining adequate air flow through the chassis 100, overall cooling performance and system reliability is enhanced.

While the fan tray 102 is extended from the chassis 100, which can be downwardly, there is sufficient clearance to easily remove and insert circuit cards, e.g., blades, into the chassis. When the fan tray 102 is rotated out to enable swapping of a fan module 110, the duct 104 acts as airflow ducting without interference from cables from blades in the chassis. These cables can be supported by a cable tray that is above the fan tray 102 to make it easier to rotate the fan tray and swap the faulty fan modules 110.

In an exemplary embodiment shown in FIG. 4, an air filter 120 can be placed in the fan tray 102 in front of the each fan module 110. When the fan tray is extended from the chassis to the second position, the air filter 120 can be easily installed in the fan tray 102. In addition, it is relatively easy to determine whether the air filter is clogged, such as by dust.

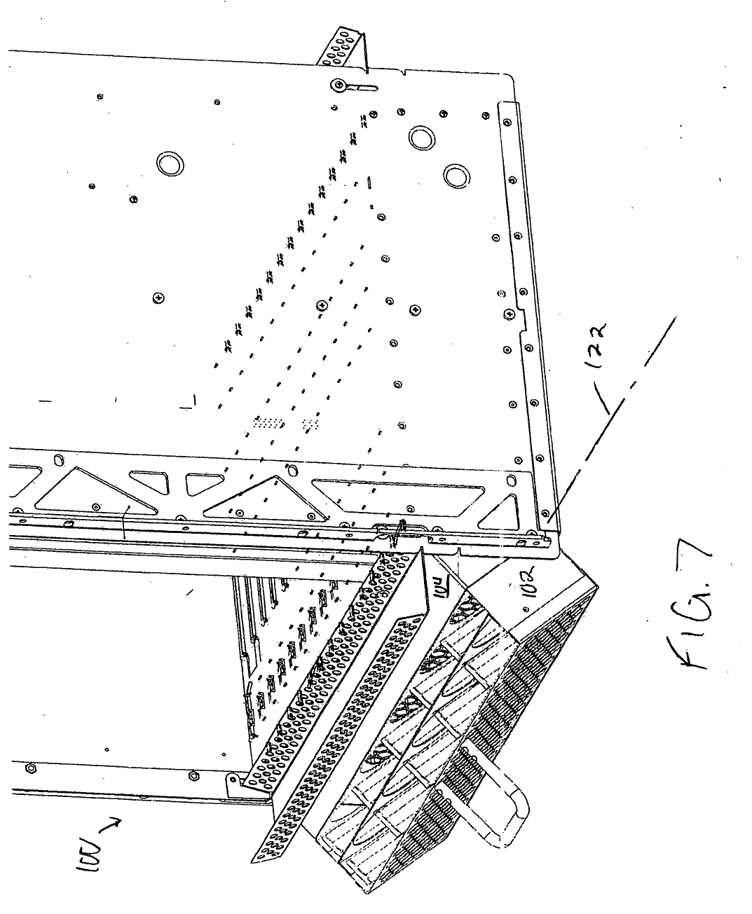

It is understood that a variety of mechanisms can be used to achieve movement of the fan tray from a first position proximate the chassis to a second position away from the chassis. In the illustrative embodiment shown in FIG. 7, for example, the fan tray 102 rotates about an axis 122 using a hinge mechanism. In alternative embodiments, fan tray can be on a guide rail that can be pulled back and forth to enable hot-swapping of fans. In another embodiment, a fan tray can be partly pulled out and then rotated. Other mechanisms to enable rotation can be used that will be readily apparent to one of ordinary skill in the art.

In other embodiments, the fan tray is more freely movable, i.e., movement is not limited to rotation about an axis. In one embodiment, the duct is of sufficient strength to maintain the fan tray secured to the chassis. A hook and latch mechanism, for example, can maintain the fan tray in the first position and the latch can be undone to enable movement of the fan tray to the second position. A wide range of mechanisms to enable movement of the fan tray from the first to the second position will be apparent to one of ordinary skill in the art. For example, the fan tray can be mounted on screws and fasteners at either end of the fan tray (towards the rear bottom part of the fan tray) and/or in the middle bottom of the fan tray for rotating mechanism. The fan tray can also be also be on guide rails that slide in and out. Another suitable mechanism for rotating the fan tray includes pivots with a hinge mechanism(s).

The duct 104 can be made from a variety of suitable materials that maintain an air flow path from the fan tray to the input air plenum. Exemplary materials include sheet metal and molded plastic.

In an exemplary embodiment, the duct 104 is formed from a plastic material that is relatively flexible to facilitate movement of the fan tray away from the chassis. In other embodiments where the duct is formed from sheet metal, the duct is relatively rigid.

In a further embodiment, a chassis includes dual fan trays that are independently movable between a first position proximate the chassis and a second position extended from the chassis to enable access to a fan module.

While exemplary embodiments show the fan tray in a front portion of a chassis, it is understood that the fan tray can be located in other portions of the chassis, such as the rear. Fans in the fan tray pull air from in front of the chassis into an input air plenum, into the chassis, through an output air plenum and through the fan modules. The fan tray in the rear of the chassis is movable from a first position proximate the chassis to a second position extended from the chassis with a duct to maintain air flow in the second position.

It is understood that the exemplary embodiments of a chassis having a movable fan tray that maintains air flow are applicable to wide variety of equipment types. In one embodiment, the chassis is provided generally in accordance with PCI Industrial Computers Manufacturers Group (PICMG), Advanced Telecommunications Computing Architecture (ATCA) (also AdvancedTCA) base specification PICMG 3.0, revision 1.0, published on Dec. 30, 2002. Many types of telecom and other types of equipment would benefit from enhanced fan module replacement with adequate air flow.

Other embodiments are within the scope of the following claims.

What is claimed is:

1. A system, comprising:
a chassis to hold a number of circuit cards;
an input air plenum to provide a path for an air flow into the chassis;
a fan tray that is movable between a first position in which the fan tray abuts the chassis and a second position in which the fan tray is extended from the chassis; and
a duct to maintain an air flow path from the fan tray to the input air plenum when the fan tray is in the second position.

2. The system according to claim 1, wherein the fan tray is located in a front portion of the chassis.

3. The system according to claim 1, wherein the chassis is an advanced telecommunications computing architecture (ATCA)-type chassis.

4. The system according to claim 1, further including an assembly having a connector to mate with a fan module connector.

5. The system according to claim 4, wherein the assembly is rigid.

6. The system according to claim 4, wherein the assembly is located at a bottom of the fan tray.

7. The system according to claim 1, wherein the fan tray includes guides to form a slot into which a fan module can be inserted.

8. The system according to claim 1, wherein the fan tray includes a slot for an air filter.

9. The system according to claim 1, wherein the fan tray pivots along an axis to move between the first and second positions.

10. The system according to claim 1, wherein the duct is substantially rigid.

11. The system according to claim 10, wherein the duct is formed from sheet metal.

12. A method, comprising:
coupling a fan tray for holding fan modules to a chassis;
coupling a duct to the fan tray and the chassis such that the duct maintains an air flow path from the fan tray to the chassis when the fan tray is moved from a first position proximate the chassis and a second position extended from the chassis.

13. The method according to claim 12, further including coupling an assembly to a lower region of the fan tray, wherein the assembly has a connector to mate with a connector of one of the fan modules.

14. The method according to claim 12, wherein the duct is substantially rigid.

15. The method according to claim 12, wherein the fan tray includes guides that form a slot for one of the fan modules.

16. A method of replacing a fan module in a chassis, comprising:
moving a fan tray from a first position to a second position from which a fan module can be removed while a duct extending from the fan tray to the chassis maintains a pathway for air flow to an interior of the chassis while the fan tray is in the second position.

17. The method according to claim 16, further including hot-swapping a faulty fan module.

18. The method according to claim 16, wherein the duct is substantially rigid.

19. A telecommunication device, comprising:
a chassis including slots for blades;
a plurality of blades in the slots;
a fan tray that is movable between a first position in which the fan tray abuts the chassis and a second position in which the fan tray is extended from the chassis; and
a duct to maintain an air flow path from the fan tray to the input air plenum when the fan tray is in the second position.

20. The device according to claim 19, wherein the duct is substantially rigid.

21. The device according to claim 19, wherein fan modules in the fan tray are hot-swappable.

22. The device according to claim 19, further including an assembly having a connector to mate with a fan connector.
